(19) United States
(12) Patent Application Publication
(10) Pub. No.: US 2009/0302893 A1
(43) Pub. Date: Dec. 10, 2009

(54) High Speed "Pseudo" Current Mode Logic (CML) Integrated Circuit Memory Latch

(76) Inventor: Sarabjeet Singh, Bangalore (IN)

Correspondence Address: IBM CORPORATION;ROCHESTER IP LAW DEPT. 917, 3605 HIGHWAY 52 NORTH, ROCHESTER, MN, 55901-7829, US

(21) Appl. No.: 12/133,620

(22) Filed: Jun. 5, 2008

(51) Int. Cl. H03K 19/20

(52) U.S. Cl. 326/115

(57) ABSTRACT

“Negative And” (NAND) logic gate metal oxide semiconductor field effect transistor (MOSFET) switch(es) are incorporated in the first stage of a “pseudo” current mode logic (CML) latch to provide a low-resistance (or high-resistance) circuit path to the output depending on the input voltage. These switch(es) are also used to deactivate (or “switch-off”) the first stage of the circuit during the second half of a timing clock cycle, so as to permit the first stage to be activated (or “switched-on”) only during the first half of a clock cycle. “Cross-coupled” inverter(s) are also used in the second stage of the circuit to provide acceptable “rail-to-rail” output voltage differential “swing” using less current. In addition, the second stage also has MOSFET switch(es) which activate (or “switch-on”) only during the second half of a timing clock cycle and are deactivated (or “switched-off”) during the first half of a clock cycle, which (in combination with operation of the first stage circuit) requires use of less current and thus reduces power consumption.

### FIELD OF THE INVENTION

This invention relates generally to “current mode logic” (CML) integrated circuit memory latches.

### BACKGROUND OF THE INVENTION

Complimentary metal oxide semiconductor field effect transistor (CMOS) “current mode logic” (CML) circuits are widely used for memory latches in very large scale integration (VLSI) computer chip design because they provide high switching speeds.

Three types of CML circuit designs are compared herein, i.e., (a) conventional CML latches; (b) prior art (or regular) “pseudo” CML latches; and (c) the “high speed” pseudo CML latch design(s) of the invention. Conventional CMOS CML latch designs use a three-layer “staggered” transistor circuit configuration involving a “current source” transistor along with “switch” transistor(s) and a “differential transistor pair” plus a resistive output load. However, this configuration has the disadvantage(s) of being unable to provide an acceptably large “rail-to-rail” output voltage differential “swing” (when transitioning from a low level to a high level or vice versa) and also demanding excessive power consumption since the current source transistor is always “on” in an activated state. Regular “pseudo” CML latch designs add a pair of MOSFET (timing clock enabled) switches in the first stage of the circuit to allow less power consumption and to provide higher output voltage differential “swing” than conventional CML latches, but this circuit cannot satisfactorily operate (and loses its low power advantage) at higher speed(s).

This invention overcomes disadvantages experienced with conventional (and regular “pseudo”) CML latch designs, including small output voltage “swing” differential and delayed circuit response time(s) occurring at high operating speeds. The problems experienced with prior art CML latches are solved by incorporating input voltage controlled metal oxide semiconductor field effect transistor (MOSFET) “Negative And” (NAND) logic gate switch(es) in the first stage of a regular “pseudo” CML latch circuit, in order to provide either a low-resistance (or high-resistance) current path to the circuit output node depending on the input voltage level. This circuit enables faster charging (and/or discharging) of the output node, and thus provides higher speed operation (through better response times) when using similar current as other (conventional and regular “pseudo”) CML circuit configurations.

### SUMMARY OF THE INVENTION

In accordance with at least one presently preferred embodiment of the present invention, there is broadly contemplated herein the incorporation of “Negative And” (NAND) logic gate metal oxide semiconductor field effect transistor (MOSFET) switch(es) in the first stage of a “pseudo” current mode logic (CML) latch to provide a low-resistance (or high-resistance) circuit path to the output depending on the input voltage. These switch(es) are also used to deactivate (or “switch-off”) the first stage of the circuit during the second half of a timing clock cycle, so as to permit the first stage to be activated (or “switched-on”) only during the first half of a clock cycle. “Cross-coupled” inverter(s) are also used in the second stage of the circuit to provide acceptable “rail-to-rail” output voltage differential “swing” using less current. In addition, the second stage also has MOSFET switch(es) which activate (or “switch-on”) only during the second half of a timing clock cycle and are deactivated (or “switched-off”) during the first half of a clock cycle, which (in combination with operation of the first stage circuit) requires use of less current and thus reduces power consumption

The “high speed” pseudo CML latch circuit of the invention uses positive channel (“p-type”) metal oxide semiconductor field effect transistor (PMOS) switch(es) in the 1st stage circuit that are controlled by the output of NAND gate(s). During the “evaluation phase” of the timing clock cycle the state of the PMOS switch(es) is dependent on the input signal level, thus allowing for more rapid and full switching of the “tail current” to enable faster charging (and discharging) of the 1^{st} stage output node and thus providing better performance. During the “latching phase” of the clock cycle the PMOS switch(es) remain deactivated (or “off”), thereby disconnecting the 1st stage circuit from the 2nd stage circuit to allow for quick voltage level retention (or “latching”) at the 2nd stage input(s) in order to produce a “full swing rail-to-rail” output.

In summary, one aspect of the invention provides a high speed integrated circuit memory latch device comprising a first and second current mode logic transistor circuit arrangement for providing:

a. a differential data input signal;

b. a differential output signal;

c. a differential timing clock signal; and

d. a power supply voltage and a bias voltage and a ground voltage;

wherein the differential timing clock signal activates one of the first circuit or the second circuit but not both at the same time such that:

(i). the first circuit operates to change the output signal value according to the level of the input signal; and

(ii). the second circuit operates to hold the output signal to the value set by the first circuit.

Another aspect of the invention provides a method of using a high speed integrated circuit memory latch device comprising a first and second current mode logic transistor circuit arrangement in a computerized system, the method comprising the steps of providing:

a. a differential data input signal;

b. a differential output signal;

c. a differential timing clock signal; and

d. a power supply voltage and a bias voltage and a ground voltage;

wherein the differential timing clock signal activates one of the first circuit or the second circuit but not both at the same time such that:

(i). the first circuit operates to change the output signal value according to the level of the input signal; and

(ii). the second circuit operates to hold the output signal to the value set by the first circuit.

Furthermore, an additional aspect of the invention provides a computerized system using a high speed integrated circuit memory latch device comprising a first and second current mode logic transistor circuit arrangement for providing:

a. a differential data input signal;

b. a differential output signal;

c. a differential timing clock signal; and

d. a power supply voltage and a bias voltage and a ground voltage;

wherein the differential timing clock signal activates one of the first circuit or the second circuit but not both at the same time such that:

(i). the first circuit operates to change the output signal value according to the level of the input signal; and

(ii). the second circuit operates to hold the output signal to the value set by the first circuit.

For a better understanding of the present invention, together with other and further features and advantages thereof, reference is made to the following description, taken in conjunction with the accompanying drawings, and the scope of the invention will be pointed out in the appended claims.

### BRIEF DESCRIPTION OF THE DRAWINGS

FIG. 1 illustrates a prior art conventional CMOS CML latch design.

FIG. 2 illustrates a prior art regular “pseudo” CML latch design.

FIG. 3 is a schematic diagram of a preferred embodiment of the “high speed” pseudo CML latch circuit of the invention.

FIG. 4 illustrates a waveform comparing the performance of prior art (conventional and regular “pseudo”) CML latch circuits.

FIG. 5 illustrates a waveform comparing the performance of a prior art regular “pseudo” CML latch circuit and the “high speed” pseudo CML latch circuit of the invention.

FIG. 6 is a simplified schematic diagram of the “high speed” pseudo CML latch circuit shown in FIG. 3.

FIG. 7 provides a plot of the input-to-output transfer characteristics of the “high speed” pseudo CML latch circuit as compared with a conventional CML latch.

### DETAILED DESCRIPTION OF THE PREFERRED EMBODIMENTS

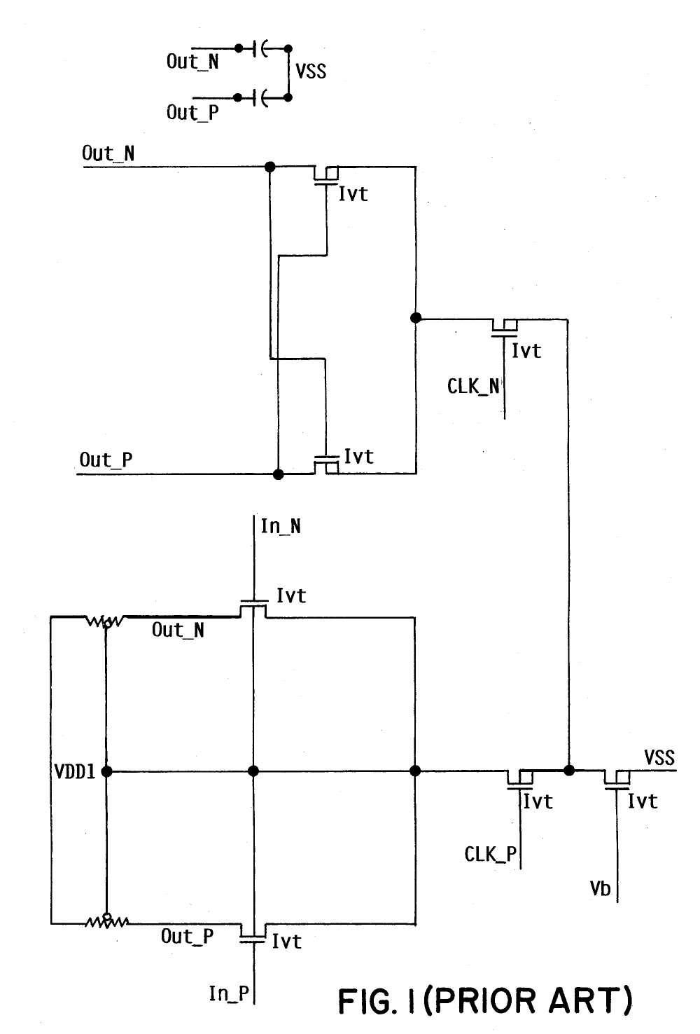

It will be readily understood that the components of the present invention, as generally described and illustrated in the Figures herein, may be arranged and designed in a wide variety of different configurations. Thus, the following more detailed description of the embodiments of the apparatus, system, and method of the present invention, as represented in FIGS. 1-7, is not intended to limit the scope of the invention, as claimed, but is merely representative of selected embodiments of the invention.

Reference throughout this specification to “one embodiment” or “an embodiment” (or the like) means that a particular feature, structure, or characteristic described in connection with the embodiment is included in at least one embodiment of the present invention. Thus, appearances of the phrases “in one embodiment” or “in an embodiment” in various places throughout this specification are not necessarily all referring to the same embodiment.

Furthermore, the described features, structures, or characteristics may be combined in any suitable manner in one or more embodiments. In the following description, numerous specific details are provided, such as examples of hardware modules, hardware circuits, hardware chips, etc., to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

The illustrated embodiments of the invention will be best understood by reference to the drawings, wherein like parts are designated by like numerals or other labels throughout. The following description is intended only by way of example, and simply illustrates certain selected embodiments of devices, systems, and processes that are consistent with the invention as claimed herein.

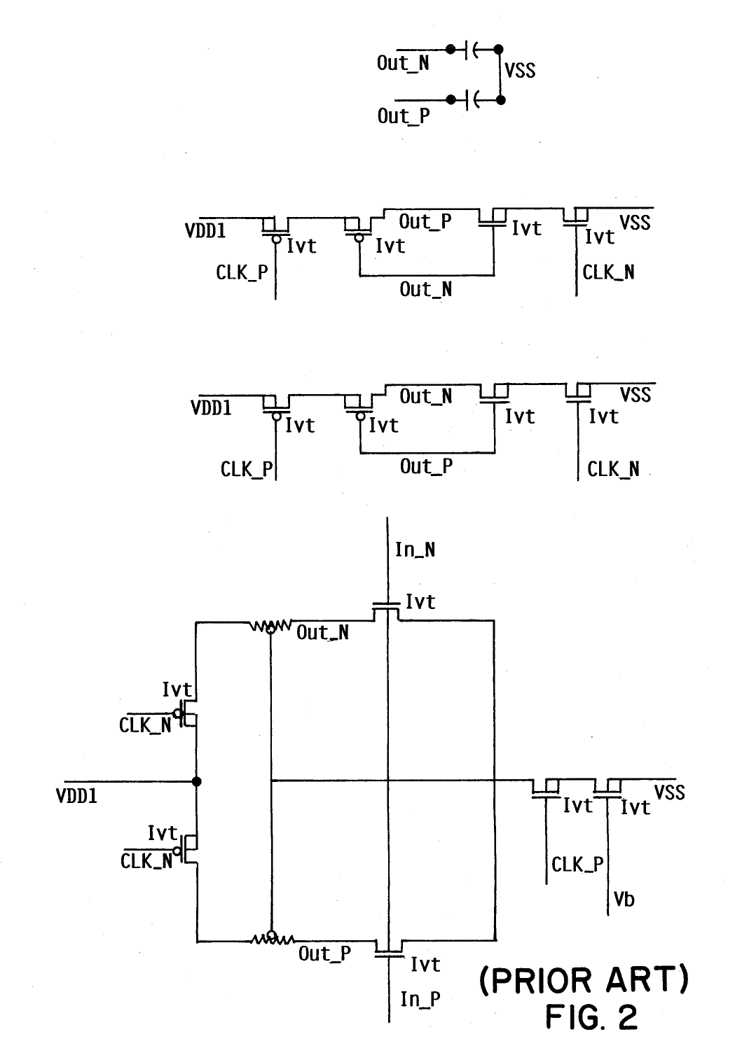

FIG. 1 illustrates a conventional CMOS CML latch design using a three-layer “staggered” transistor circuit configuration involving a “current source” transistor along with “switch” transistor(s) and a “differential transistor pair” plus a resistive output load. FIG. 2 illustrates a prior art regular “pseudo” CML latch design adding a pair of MOSFET (timing clock enabled) switches in the first stage of the circuit to allow less power consumption and to provide higher output voltage differential “swing”.

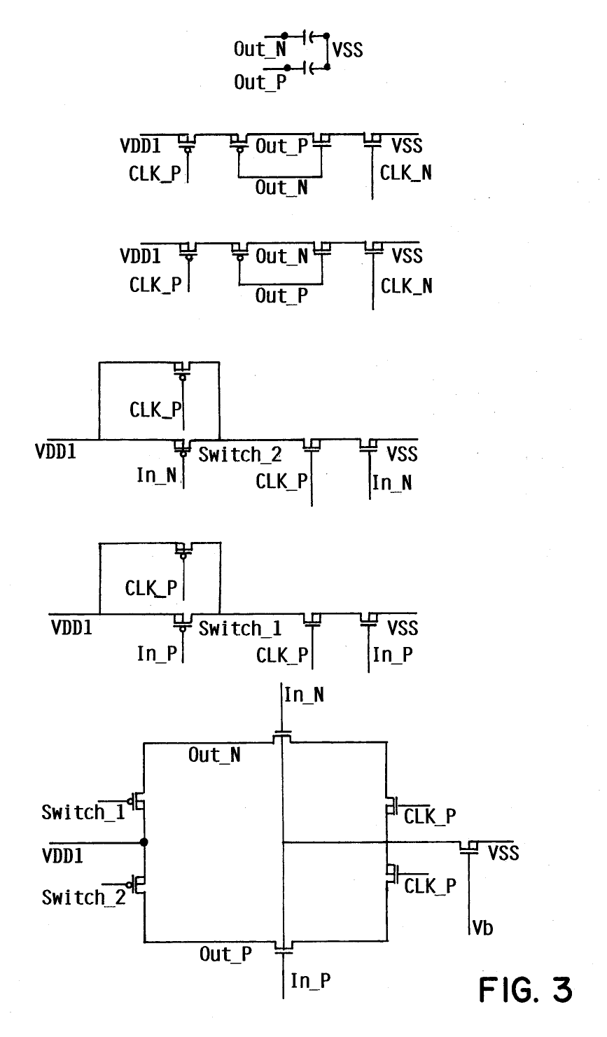

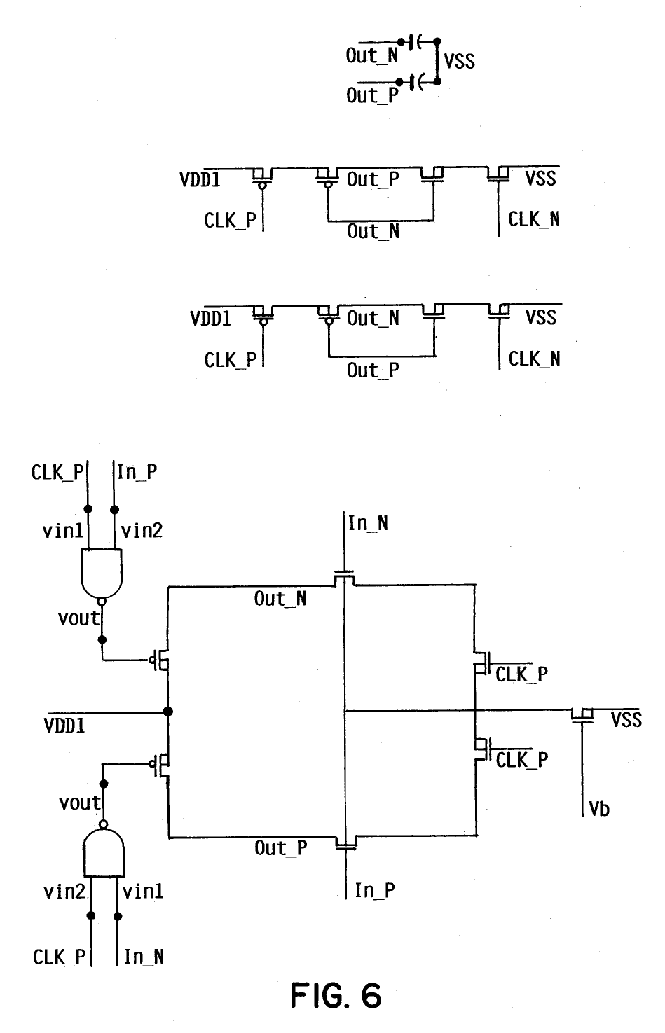

FIG. 6 is a simplified diagram of the schematic configuration of a preferred embodiment of the “high speed” pseudo CML latch circuit of the invention (as also shown in FIG. 3) consisting of the following signal elements:
1. differential data input signal (In_P & In_N)
2. differential output signal (Out_P & Out_N)
3. differential timing clock signal (CLK_P & CLK_N)
4. power supply voltage (VDD1)
5. bias voltage (Vb)
6. ground voltage (VSS)

As shown in the preferred embodiment of FIG. 3 & FIG. 6, the first stage of the “high speed” pseudo CML latch circuit consists of input-assisted positive channel (“p-type”) metal oxide semiconductor field effect transistor (PFET) switches controlled by the output (Vout) of a pair of “Negative And” (NAND) logic gates, along with input negative channel (“n-type”) metal oxide semiconductor field effect transistor(s) (NFETs) (In_P & In_N) as well as timing clock (CLK_P) NFET switch(es) and a current bias NFET for providing bias current using bias voltage (Vb). The second stage of the circuit consists of a pair of “cross-coupled” inverters for holding the output signal value (Out_P & Out_N) using MOSFET clock switch(es) (CLK_P & CLK_N) with output load (Out_P & Out_N) modeled by “ideal” capacitors to common ground (VSS). The first inverter consists of a (CLK_P) PFET switch along with a middle PFET+NFET inverter (having Out_P as input) and a (CLK_N) NFET switch, while the second inverter consists of a (CLK_P) PFET switch along with a middle PFET+NFET inverter (having Out_N as input) and a (CLK_N) NFET switch.

Since the timing clock signal is differential (i.e. only one of CLK_P or CLK_N takes a high value at a given point in time) either the first stage circuit or the second stage circuit (but not both) are operating at any point in time, since the (CLK_P) PFET “switches off” the first stage circuit to allow its disconnection during operation of the second stage circuit. When CLK_P is at a high level then the first stage circuit is operating to quickly change the output signal (Out_P & Out_N) according to the input signal level (In_P & In_N). When CLK_P is at a low level (i.e. CLK_N is high) then the second stage circuit is operating to hold (or “latch”) the output signal (Out_P & Out_N) to the value set by the first stage input (In_P & In_N).

As shown in FIG. 3 & FIG. 6, the first stage of the “high speed” pseudo CML latch circuit operates by directing (or “steering”) bias current to the appropriate circuit branch to change the output signal (Out_P & Out_N) according to the input signal level (In_P & In_N). When In_P is at a low level (i.e In_N is high) then the NFET (connected to In_P) is deactivated (or “off”) and the entire bias current (created by Vb at the bottom biasing NFET) flows through the other NFET (connected to In_N) which is activated (or “on”). Also, the top PFET switch (controlled by inputs CLK_P & In_N) activates (or “switches on”) thereby driving (or “pulling”) its output (Out_P) to a high level and the PFET switch (controlled by inputs CLK_P & In_P) deactivates (or “switches off”) thereby allowing biasing current to drive (or “pull”) its output (Out_N) to a low level. (The opposite sequence occurs when In_P is high.) The second stage of the “high speed” pseudo CML latch circuit uses positive feedback from “cross-coupled” inverters to hold (or “latch”) the output signal (Out_P & Out_N) to the value set by the first stage circuit. When Out_P is at a high level then the inverter (having an input connected to Out_P) drives (or “pulls”) Out_N to a lower value and the other inverter (having an input connected to Out_N) drives (or “pulls”) Out_P to a higher value, thereby holding (or “latching”) the value of Out_P & Out_N and thus enabling “full rail-to-rail” output voltage differential “swing” and also consuming less power.

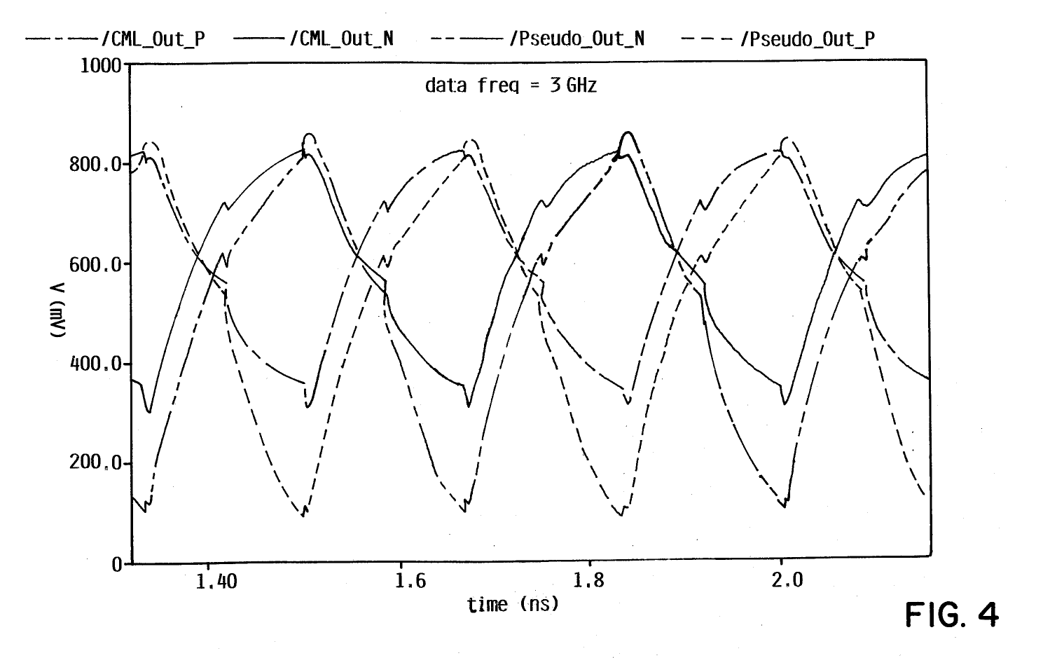

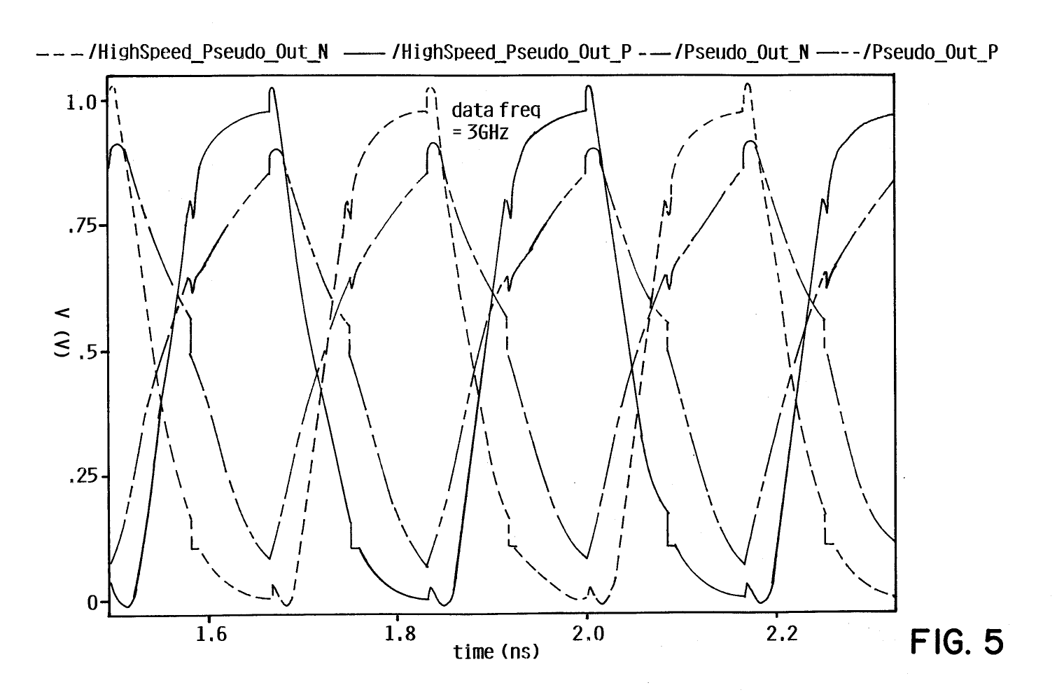

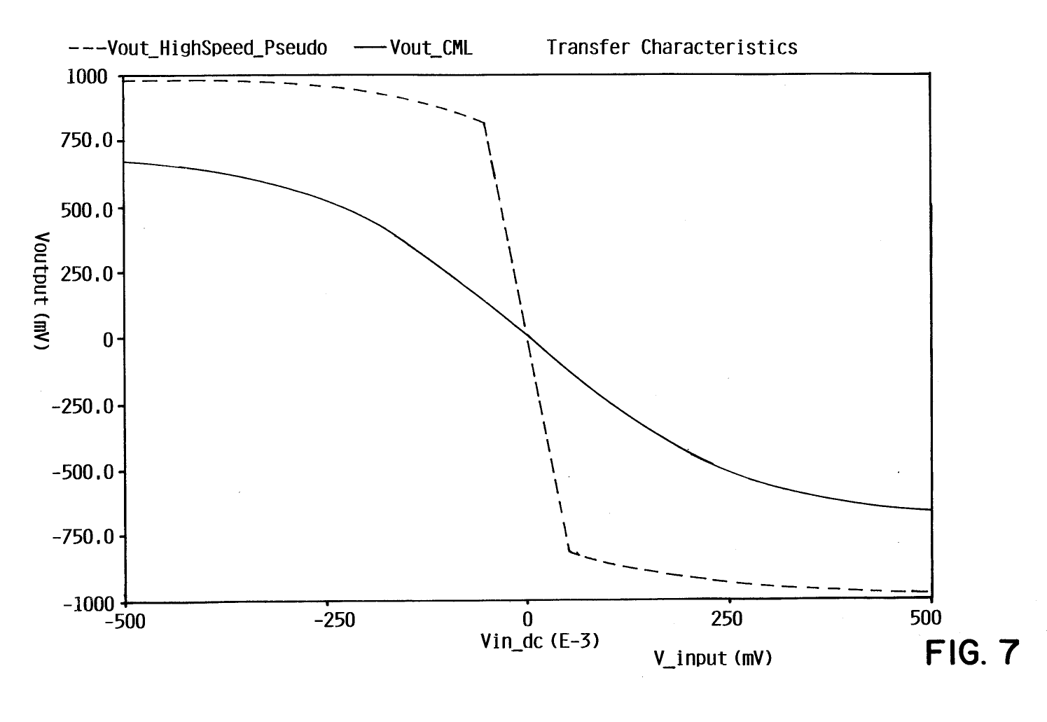

As seen from the waveform in FIG. 4, both prior art (conventional and regular “pseudo”) CML circuits have poor “rise/fall” response times and a small output voltage differential “swing” (i.e. not “full rail-to-rail”) at high speed (3 Ghz). As seen from the waveform in FIG. 5, the output voltage differential “swing” of the invention is “full rail-to-rail” (i.e. ranging from ground (0V) to supply voltage (1V) value of VDD1) even at high speed (3 Ghz) and that it also provides better “rise & fall” response times for the output. FIG. 7 provides a plot of the input-to-output transfer characteristics of the first (1^{st}) stage of the “high speed” pseudo CML latch circuit as compared with a conventional CML latch, showing that the “high speed” circuit provides better output voltage differential “swing” (i.e., “full rail-to-rail” from +1V to −1V) since it transitions (from low->high and high->low between +50 mV to −50 mV) faster than other CML latch circuits.

Table (I) provides measured circuit response parameters at clock frequencies of one (1 GHz) and three (3 GHz) gigahertz, showing that the “high speed” pseudo CML latch performs better than other (conventional and regular “pseudo”) CML circuits at higher speed(s) since these other circuits fail to operate properly at high frequencies:

| | Rise Time | Fall Time | | | |
|---|---|---|---|---|---|
| | (+/−0.1 V | (+/−0.1 V | Output voltage | | |
| | around | around | swing during | | |
| | common mode | common mode | evaluation | Final output | |
| | output) | output) | phase | voltage swing | Avg Current |
| During Evaluation | | | | | |
| phase | | | | | |
| (freq = 1 GHz) | | | | | |
| High Speed | 11.7 ps | 15.9 ps | 953 mV | 998 mV | 1.7 mA |
| Pseudo - CML | | | | | |
| Pseudo - CML | 45 ps | 30.5 ps | 601 mV | 901 mV | 3.0 mA |
| CML | 35.8 ps | 42.8 ps | 555 mV | 678 mV | 4.7 mA |
| During Evaluation | | | | | |
| phase | | | | | |
| (freq = 3 GHz) | | | | | |
| High Speed | 10.6 ps | 18 ps | 637 mV | 965 mV | 4.4 mA |
| Pseudo - CML | | | | | |
| Pseudo - CML | Fail, as | Fail, as voltage | 99 mV | 779 mV | 4.2 mA |
| | voltage swing | swing is only | | | |
| | is only 0.01 V | 0.01 V | | | |
| | (<0.2 V) | (<0.2 V) | | | |
| CML | Fail, as | Fail, as voltage | 173 mV | 507 mV | 4.9 mA |
| | voltage swing | swing is only | | | |
| | is only 0.173 V | 0.173 V | | | |
| | (<0.2 V) | (<0.2 V) | | | |

It is to be understood that the present invention, in accordance with at least one presently preferred embodiment, includes elements that may be implemented on at least one general-purpose computer. These may also be implemented on at least one Integrated Circuit or part of at least one Integrated Circuit. Thus, it is to be understood that the invention may be implemented in hardware, software, or a combination of both.

If not otherwise stated herein, it is to be assumed that all patents, patent applications, patent publications and other publications (including web-based publications) mentioned and cited herein are hereby fully incorporated by reference herein as if set forth in their entirety herein.

Although illustrative embodiments of the present invention have been described herein with reference to the accompanying drawings, it is to be understood that the invention is not limited to those precise embodiments, and that various other changes and modifications may be affected therein by one skilled in the art without departing from the scope or spirit of the invention.

What is claimed is:

1. A high speed integrated circuit memory latch device comprising a first and second current mode logic transistor circuit arrangement for providing:
a. a differential data input signal;
b. a differential output signal;
c. a differential timing clock signal; and
d. a power supply voltage and a bias voltage and a ground voltage;
wherein the differential timing clock signal activates one of the first circuit or the second circuit but not both at the same time such that:
(i). the first circuit operates to change the output signal value according to the level of the input signal; and
(ii). the second circuit operates to hold the output signal to the value set by the first circuit.

2. The high speed integrated circuit memory latch device of claim 1 further comprising:
a. one or more p-type MOSFET switch(es) in the first circuit each controlled by the output of a NAND gate driven by the differential data input and timing clock signal(s) to:
(i). change the output signal value depending on the level of the input signal; or
(ii). disconnect the first circuit from the second circuit; and
b. at least one cross-coupled inverter in the second circuit to retain the output signal level.

3. The high speed integrated circuit memory latch device of claim 2 wherein:
a. the first circuit further comprises:
(i). a pair of input-assisted PFET switches each controlled by the output of a NAND gate;
(ii). a pair of input NFETs;
(iii). at least one timing clock NFET switch; and
(iv). a current bias NFET for providing bias current using the bias voltage; and
b. the second circuit comprises a pair of cross-coupled inverters each comprising a PFET switch along with a PFET+NFET inverter and an NFET switch.

4. A method of using a high speed integrated circuit memory latch device comprising a first and second current mode logic transistor circuit arrangement in a computerized system, the method comprising the steps of providing:
a. a differential data input signal;
b. a differential output signal;
c. a differential timing clock signal; and
d. a power supply voltage and a bias voltage and a ground voltage;
wherein the differential timing clock signal activates one of the first circuit or the second circuit but not both at the same time such that:
(i). the first circuit operates to change the output signal value according to the level of the input signal; and
(ii). the second circuit operates to hold the output signal to the value set by the first circuit.

5. The method of claim 4 wherein the high speed integrated circuit memory latch device further comprises:
a. one or more p-type MOSFET switch(es) in the first circuit each controlled by the output of a NAND gate driven by the differential data input and timing clock signal(s) to:
(i). change the output signal value depending on the level of the input signal; or
(ii). disconnect the first circuit from the second circuit; and
b. at least one cross-coupled inverter in the second circuit to retain the output signal level.

6. The method of claim 5 wherein:
a. the first circuit further comprises:
(i). a pair of input-assisted PFET switches each controlled by the output of a NAND gate;
(ii). a pair of input NFETs;
(iii). at least one timing clock NFET switch; and
(iv). a current bias NFET for providing bias current using the bias voltage; and
b. the second circuit comprises a pair of cross-coupled inverters each comprising a PFET switch along with a PFET+NFET inverter and an NFET switch.

7. A computerized system using a high speed integrated circuit memory latch device comprising a first and second current mode logic transistor circuit arrangement for providing:
a. a differential data input signal;
b. a differential output signal;
c. a differential timing clock signal; and
d. a power supply voltage and a bias voltage and a ground voltage;
wherein the differential timing clock signal activates one of the first circuit or the second circuit but not both at the same time such that:
(i). the first circuit operates to change the output signal value according to the level of the input signal; and
(ii). the second circuit operates to hold the output signal to the value set by the first circuit.

8. The system of claim 7 wherein the high speed integrated circuit memory latch device further comprises:
a. one or more p-type MOSFET switch(es) in the first circuit each controlled by the output of a NAND gate driven by the differential data input and timing clock signal(s) to:
(i). change the output signal value depending on the level of the input signal; or
(ii). disconnect the first circuit from the second circuit; and
b. at least one cross-coupled inverter in the second circuit to retain the output signal level.

9. The system of claim 8 wherein:
a. the first circuit further comprises:
(i). a pair of input-assisted PFET switches each controlled by the output of a NAND gate;
(ii). a pair of input NFETs;
(iii). at least one timing clock NFET switch; and
(iv). a current bias NFET for providing bias current using the bias voltage; and
b. the second circuit comprises a pair of cross-coupled inverters each comprising a PFET switch along with a PFET+NFET inverter and an NFET switch.
